(19) United States
(12) Patent Application Publication
(10) Pub. No.: US 2026/0353656 A1
(43) Pub. Date: Nov. 5, 2026

(54) SEMICONDUCTOR DEVICES INCLUDING SEPARATION REGION AND DATA STORAGE SYSTEMS INCLUDING THE SAME

(71) Applicant: SAMSUNG ELECTRONICS CO., LTD., Suwon-si (KR)

(72) Inventors: Eunsong LEE, Suwon-si (KR); Kyeongjin PARK, Suwon-si (KR); Youngjin JUNG, Suwon-si (KR)

(73) Assignee: SAMSUNG ELECTRONICS CO., LTD., Suwon-si (KR)

(21) Appl. No.: 19/404,604

(22) Filed: Dec. 1, 2025

(30) Foreign Application Priority Data
Apr. 30, 2025 (KR) 10-2025-0057418

(51) Int. Cl. H10B 43/27; H10B 41/10; H10B 41/27; H10B 43/10; H10B 80/00; H10W 80/00; H10W 90/00; H10W 90/26

(52) U.S. Cl. CPC H10B 43/27; H10B 41/10; H10B 41/27; H10B 43/10; H10B 80/00; H10W 80/312; H10W 90/26; H10W 90/792

(57) ABSTRACT

A semiconductor device including: a stack of insulating layers and electrodes; a channel structure and separation regions penetrating the stack; and a conductive layer on the stack. The separation regions include: a through portion penetrating the stack; head portions protruding into the conductive layer; and side protrusions protruding toward the electrodes; a first-side insulating layer between the separation regions and the electrodes; a second-side insulating layer on an inner surface of the first-side insulating layer; and a insulating layer on an inner surface of the second-side insulating layer. The side protrusions include: a first horizontal insulating layer including a portion of the second-side insulating layer protruding toward an electrode; and a second horizontal insulating layer including a portion of the first-side insulating layer folded along the first horizontal insulating layer. The second horizontal insulating layer is in contact with an upper and lower surfaces of adjacent side protrusions.

### CROSS-REFERENCE TO RELATED APPLICATION

This application claims benefit of priority to Korean Patent Application No. 10-2025-0057418, filed on Apr. 30, 2025 in the Korean Intellectual Property Office, the disclosure of which is incorporated herein by reference in its entirety.

### BACKGROUND

The present disclosure relates to a semiconductor device and a data storage system including the same.

A semiconductor device capable of storing a large amount of data is required in a data storage system requiring data storage. Accordingly, methods for increasing data storage capacity of a semiconductor device are being studied. For example, as one of the methods for increasing the data storage capacity of a semiconductor device, a semiconductor device including memory cells disposed three-dimensionally, instead of memory cells disposed two-dimensionally, has been proposed.

### SUMMARY

Provided is a data storage system including a semiconductor device having improved reliability.

According to an aspect of the disclosure, a semiconductor device includes: a stack structure including interlayer insulating layers and gate electrodes stacked in a first direction; a channel structure penetrating through the stack structure to extend in the first direction; a conductive layer on the stack structure; and separation regions penetrating through the stack structure to extend in a second direction perpendicular to the first direction, and spaced apart from each other in a third direction perpendicular to the first direction and the second direction, wherein each of the separation regions includes: a separation region through portion penetrating through the stack structure; at least one separation region head portion protruding into the conductive layer; and side protrusion portions protruding from a side surface of the separation region through portion toward the gate electrodes, wherein the side protrusion portions are spaced apart from each other in the first direction; a first-side insulating layer between the separation regions and the gate electrodes; a second-side insulating layer on an inner side surface of the first-side insulating layer; and a buried insulating layer on an inner side surface of the second-side insulating layer, and wherein each of the side protrusion portions of each of the separation regions includes: a first horizontal insulating layer including a portion of the second-side insulating layer protruding toward one of the gate electrodes; and a second horizontal insulating layer including a portion of the first-side insulating layer folded along the first horizontal insulating layer, wherein the second horizontal insulating layer of each of the side protrusion portions is in contact with an upper surface of the first horizontal insulating layer of a first side protrusion portion among the side protrusion portions and is in contact with a lower surface of the first horizontal insulating layer of a second side protrusion portion among the side protrusion portions, wherein the first side protrusion portion is adjacent to the second side protrusion portion in the first direction

According to an aspect of the disclosure, a semiconductor device includes: a first semiconductor structure including a first substrate, a circuit element on the first substrate, a lower interconnection structure connected to the circuit element, and a lower bonding structure connected to the lower interconnection structure; and a second semiconductor structure on the first semiconductor structure, the second semiconductor structure including an upper bonding structure bonded to the lower bonding structure, wherein the second semiconductor structure includes: a conductive layer; a stack structure below the conductive layer and including interlayer insulating layers and gate electrodes, stacked in a first direction perpendicular to an upper surface of the conductive layer; an upper interconnection structure below the stack structure and joined to the upper bonding structure; a channel structure including a channel layer joined to the conductive layer, the channel structure penetrating through the stack structure in the first direction; and a separation region, wherein the separation region includes: a separation region through portion penetrating through the stack structure in a second direction perpendicular to the first direction; separation region head portions protruding from the separation region through portion into the conductive layer and spaced apart from each other in the second direction, a side insulating layer contacting a side surface of the separation region through portion; a buried insulating layer in an inside of the side insulating layer; and an upper buried insulating layer extending in the first direction from the buried insulating layer and protruding into an internal portion of the conductive layer from the separation region head portions, and wherein the upper buried insulating layer is in contact with the conductive layer.

According to an aspect of the disclosure, a semiconductor device includes: a semiconductor device including an input/output pad; and a controller connected to the semiconductor device through the input/output pad and configured to control the semiconductor device, wherein the semiconductor device includes: a stack structure including interlayer insulating layers and gate electrodes stacked in a first direction; a channel structure penetrating through the stack structure to extend in the first direction; a conductive layer on the stack structure; and separation regions penetrating through the stack structure to extend in a second direction perpendicular to the first direction, and spaced apart from each other in a third direction perpendicular to the first direction and the second direction, wherein each of the separation regions includes: a separation region through portion penetrating through the stack structure; at least one separation region head portion protruding into the conductive layer; and side protrusion portions protruding from a side surface of the separation region through portion toward the gate electrodes, wherein the side protrusion portions are spaced apart from each other in the first direction; a first-side insulating layer between the separation regions and the gate electrodes; a second-side insulating layer on an inner side surface of the first-side insulating layer; and a buried insulating layer on an inner side surface of the second-side insulating layer, and wherein each of the side protrusion portions of each of the separation regions includes: a first horizontal insulating layer including a portion of the second-side insulating layer protruding toward one of the gate electrodes; and a second horizontal insulating layer including a portion of the first-side side insulating layer folded along the first horizontal insulating layer, wherein the second horizontal insulating layer of each of the side protrusion portions is in contact with an upper surface of the first horizontal insulating layer of a first side protrusion portion among the side protrusion portions and is in contact with a lower surface of the first horizontal insulating layer of a second side protrusion portion among the side protrusion portions, wherein the first side protrusion portion is adjacent to the second side protrusion portion in the first direction.

### BRIEF DESCRIPTION OF DRAWINGS

The above and other aspects and features of certain embodiments of the present disclosure will be more clearly understood from the following detailed description taken in conjunction with the accompanying drawings, in which:

FIG. 1 is a schematic plan view of a semiconductor device according to one or more embodiments;

FIG. 2 is a schematic cross-sectional view of a semiconductor device according to one or more embodiments;

FIGS. 3-5 are partially-enlarged, cross-sectional views of a semiconductor device according to one or more embodiments;

FIG. 6 is a schematic cross-sectional view of a semiconductor device according to one or more embodiments;

FIGS. 7A, 7B, 7C, 7D, 7E, 7F, 7G, 7H, 7I, 7J, 7K, and 7L are schematic cross-sectional views illustrating a method of manufacturing a semiconductor device according to one or more embodiments;

FIG. 8 is a view schematically illustrating a data storage system including a semiconductor device according to an one or more embodiments; and

FIG. 9 is a perspective view schematically illustrating a data storage system including a semiconductor device according to an one or more embodiments.

### DETAILED DESCRIPTION

Hereinafter, one or more embodiments will be described with reference to the attached drawings. Hereinafter, terms such as “on,” “above,” “upper portion,” “upper surface,” “below,” “lower portion,” “lower surface,” “side surface,” or the like can be understood to refer to the drawings, except in cases to be indicated separately by drawing symbols.

In the following description, like reference numerals refer to like elements throughout the specification. Terms such as “unit”, “module”, “member”, and “block” may be embodied as hardware or software. As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element, wherein the indirect connection may include “connection via a wireless communication network”.

Also, when a part “includes” or “comprises” an element, unless there is a particular description contrary thereto, the part may further include other elements, not excluding the other elements.

Throughout the description, when a member is “on” another member, this includes not only a configuration where the member is in contact with the other member, but also a configuration where there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, the disclosure is not be limited by these terms, and these terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated or described order unless the context clearly indicates otherwise. One or more steps or operations may be omitted unless the context of the disclosure clearly indicates otherwise.

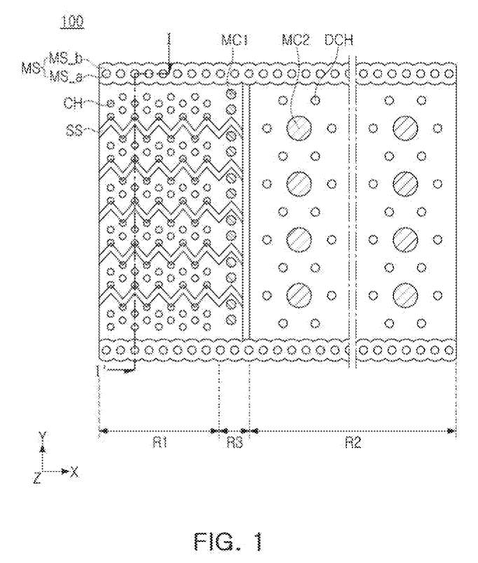

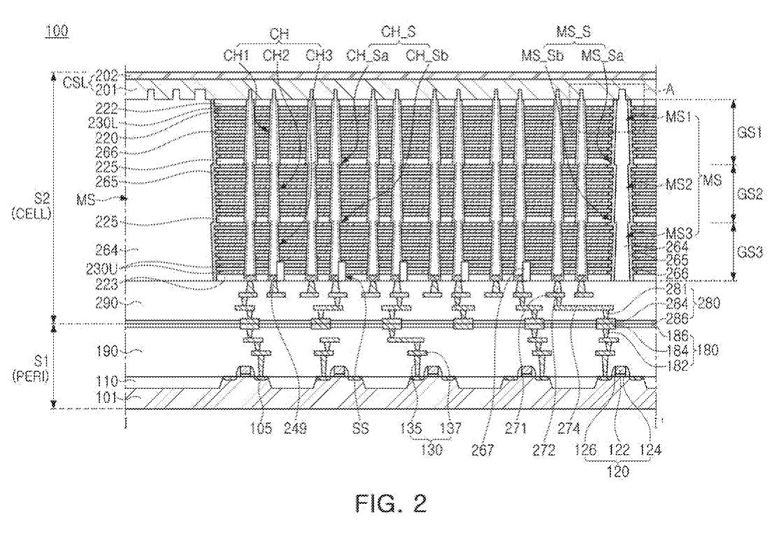

Hereinafter, a semiconductor device according to one or more embodiments will be described with reference to FIG. 1 and FIG. 2.

FIG. 1 is a schematic plan view of a semiconductor device according to one or more embodiments.

FIG. 2 is a schematic cross-sectional view of a semiconductor device according to one or more embodiments. FIG. 2 illustrates a cross-section of FIG. 1, taken along line Ⅰ-Ⅰ’.

Referring to FIG. 1, a semiconductor device 100 may include a first region R1 and a second region R2 on one side of the first region R1 in an X-direction. An upper contact region R3 may be disposed between the first region R1 and the second region R2. The first region R1 may be a memory cell region in which memory cell strings are disposed, and may be a region in which channel structures CH are disposed. A memory block may be disposed as a plurality of memory blocks in the first region R1, and tens to hundreds of memory blocks may be disposed in the first region R1.

The channel structures CH may be disposed to be spaced apart from each other, in rows and columns, on a lower surface of a first conductive layer 201 of the first region R1. The channel structures CH may be disposed in a zigzag shape on an X-Y plane in one direction.

Separation regions MS may be disposed to penetrate at least a portion of gate electrodes 230 and extend in the X-direction. The separation regions MS may be disposed parallel to each other. The separation regions MS may extend as one in the X-direction, but may extend intermittently in some regions or may be disposed only in some regions. The separation regions MS may be formed to have a curved surface on the side surface, and may have a structure in which a curved surface having a convex curvature toward an external space is continuously formed. As above, a curved structure on a side surface may be derived by forming a plurality of separation holes separated from each other at the same time as forming a channel hole, and then expanding the plurality of separation holes to be connected to each other through a cleaning process to form the separation regions MS.

Insulating regions SS may extend across the first region R1 and the upper contact region R3 in the X-direction, between adjacent separation regions MS. The insulating regions SS may be disposed across a portion of the channel structures CH. The insulating regions SS may have a predetermined width in the Y-direction, and may extend across a plurality of channel structures CH disposed in a zigzag shape in the X-direction.

The insulating regions SS may penetrate an upper gate electrode 230U disposed on an uppermost end among gate electrodes 230. As illustrated in FIG. 2, the upper gate electrode 230U may be divided in the Y-direction. The number of gate electrodes 230U separated by the insulating regions SS may be variously changed in one or more embodiments. The insulating regions SS may penetrate an upper end portion of the channel structures CH, for example, a portion of the channel structure CH facing one gate electrode 230U, and thus a portion of the channel structures CH may be removed. In this case, the channel structures CH may be penetrated by a length, smaller than a radius of the channel structure CH from a channel center axis, into an inner wall of the channel hole. Therefore, the insulating regions SS may be disposed such that the channel structure CH does not pass through the channel center axis of the channel structure CH and half or more of the channel structure CH remains on the upper surface, but the disclosure is not limited thereto. The insulating regions SS may each include an upper separation insulating layer 267. The upper separation insulating layer 267 may include an insulating material, and may include, for example, silicon oxide, silicon nitride, or silicon oxynitride.

The second region R2 may correspond to a region for electrically connecting the channel structures CH with peripheral circuit structures, and may be a region in which a plurality of word line contact plugs MC2 connected to the gate electrodes at different levels may be disposed for this purpose, but the disclosure is not limited thereto.

The second region R2 may have dummy channel structures DCH. The dummy channel structures DCH may have the same or similar structure as the channel structures CH, but may not be electrically connected to upper interconnection structures, or may not form a memory cell string in the semiconductor device 100, unlike the channel structures CH.

The dummy channel structures DCH may be regularly disposed in rows and columns in the second region R2. The dummy channel structures DCH may have a diameter, smaller than a maximum diameter of the word line contact plugs MC2. Shapes of, the number of, and/or intervals of the dummy channel structures DCH may be different. The dummy channel structures DCH may not be electrically connected to upper interconnection structures, or may not form a memory cell string, unlike the channel structures CH in the semiconductor device 100.

The upper contact region R3 may be defined as a region in which upper contact plugs MC1 connected to upper gate electrodes 230U are disposed, and as a region in which upper contact plugs MC1 for connecting erase gate electrodes and string selection gate electrodes 230, which may be string selection lines, are disposed, respectively.

Referring to FIG. 2, a semiconductor device 100 may include a peripheral circuit structure PERI, which may be a first semiconductor structure S1 in which a peripheral circuit region is formed on a first substrate 101, and a memory cell structure CELL, which may be a second semiconductor structure S2 including a common source line CSL.

The semiconductor device 100 may include a first semiconductor structure S1 defined as a peripheral circuit structure PERI, and a second semiconductor structure S2 defined as a memory cell structure CELL on the first semiconductor structure S1. The first semiconductor structure S1 and the second semiconductor structure S2 may be joined to each other through a bonding structure (180 and 280).

The first semiconductor structure S1 may include a first substrate 101, and circuit elements 120, a lower interconnection structure 130, a lower bonding structure 180, and a lower capping layer 190, on the first substrate 101.

The first substrate 101 may include a semiconductor material, such as a group IV semiconductor, a group III-V compound semiconductor, or a group II-VI compound semiconductor. The first substrate 101 may be provided as a bulk wafer or an epitaxial layer. An active region may be defined by element isolation layers 110 in the first substrate 101. Source/drain regions 105 including impurities may be disposed in a portion of the active region.

The circuit elements 120 may include a transistor. Each of the circuit elements 120 may include a circuit gate dielectric layer 122, a circuit gate electrode 124, a spacer layer 126, and source/drain regions 105. The source/drain regions 105 including impurities may be disposed in the first substrate 101 on both sides of the circuit gate electrode 124. The spacer layers 126 may be disposed on both sides of the circuit gate electrode 124. The circuit gate dielectric layer 122 may include silicon oxide, silicon nitride, or a high-κ material. The circuit gate electrode 124 may include at least one of doped silicon, titanium nitride (TiN), tantalum nitride (TaN), and tungsten nitride (WN), titanium silicon nitride (TiSiN), tantalum silicon nitride (TaSiN), tungsten silicon nitride (WSiN), tungsten (W), copper (Cu), aluminum (Al), molybdenum (Mo), or ruthenium (Ru). For example, the circuit gate electrode 124 may include a doped polycrystalline silicon layer. According to one or more embodiments, the circuit gate electrode 124 may be configured as two or more multilayers.

The lower interconnection structure 130 may be electrically connected to the circuit gate electrodes 124 and the source/drain regions 105 of the circuit elements 120. The lower interconnection structure 130 may include lower contact plugs 135 and lower interconnection lines 137 of which at least one region is a linear shape. Some of the lower contact plugs 135 may be connected to the source/drain regions 105, and another portion of the lower contact plugs 135 may be connected to the circuit gate electrodes 124. The lower contact plugs 135 may electrically connect the lower interconnection lines 137 disposed at different levels from the upper surface of the first substrate 101 to each other. The lower interconnection structure 130 may include a conductive material, and may include, for example, tungsten (W), copper (Cu), aluminum (Al), or the like, and each of components thereof may further include a diffusion barrier including at least one of titanium (Ti), titanium nitride (TiN), tantalum (T1), tantalum nitride (T1N), or tungsten nitride (WN). According to one or more embodiments, the number of layers and arrangement of the lower contact plugs 135 and the lower interconnection lines 137 constituting the lower interconnection structure 130 may be variously changed.

The lower bonding structure 180 may be connected to the lower interconnection structure 130. The lower bonding structure 180 may include a lower bonding via 182, a lower bonding pad 184, and a lower bonding insulating layer 186. The lower bonding via 182 may be connected to the lower interconnection structure 130. The lower bonding pad 184 may be connected to the lower bonding via 182. The lower bonding via 182 and the lower bonding pad 184 may include a conductive material, and may include, for example, tungsten (W), copper (Cu), aluminum (Al), or the like, and each of components thereof may further include a diffusion barrier. The lower bonding insulating layer 186 may also function as a diffusion barrier of the lower bonding pad 184, and may include at least one of silicon oxide, silicon nitride, silicon oxynitride, or silicon oxycarbide. The lower bonding insulating layer 186 may have a thickness, thinner than a thickness of the lower bonding pad 184, but the disclosure is not limited thereto. The lower bonding structure 180 may be in direct contact with and joined or connected to an upper bonding structure 280 by hybrid bonding. For example, the lower bonding pad 184 may be in contact with and coupled to an upper bonding pad 284 by copper-to-copper bonding, and the lower bonding insulating layer 186 may be in contact with and coupled to an upper bonding insulating layer 286 by dielectric-to-dielectric bonding. The lower bonding structure 180 may provide an electrical connection path between the peripheral circuit structure (S1:PERI) and the memory cell structure (S2:CELL) together with the upper bonding structure 280.

The lower capping layer 190 may be disposed on the first substrate 101 to cover the circuit elements 120 and the lower interconnection structure 130. The lower capping layer 190 may include a plurality of insulating layers. The lower capping layer 190 may include an insulating material, such as silicon oxide, silicon nitride, silicon oxynitride, silicon oxycarbide, or the like.

The second semiconductor structure S2, which may be a memory cell structure, may include a first conductive layer 201 in a first region R1, which may be a memory cell region, a second conductive layer 202 on an upper surface of the first conductive layer 201, gate electrodes 230 stacked on a lower surface of the first conductive layer 201, interlayer insulating layers 220 alternately stacked with the gate electrodes 230, channel structures CH disposed to penetrate the gate electrodes 230, separation regions MS extending in one direction through the gate electrodes 230, and insulating regions SS penetrating portions of the gate electrodes 230. An upper capping layer 290 covering the gate electrodes 230 may be further included. The gate electrodes 230 may be vertically spaced apart and stacked on the lower surface of the first conductive layer 201 to form stack structures GS1, GS2, and GS3 having a plurality of stages, together with the interlayer insulating layers 220.

In FIG. 2, an example embodiment is illustrated as including first to third stack structures GS1, GS2, and GS3, but the disclosure is not limited thereto, and may be configured as three to five stages.

The stages of the stack structures GS may be classified by a height of the stack structure that enables a channel hole process of a predetermined depth of the channel structure CH, and may be distinguished by each channel portion CH1, CH2, and CH3 of the channel structure CH. A lower stack structure located on the upper surface of the first conductive layer 201 may be termed a first stack structure GS1, and the stack structures GS2 and GS3 on the first stack structure GS1 may be sequentially referred to as a second stack structure GS2 and a third stack structure GS3.

In the stack structures GS1 to GS3, the gate electrodes 230 and the interlayer insulating layers 220 may be alternately stacked in the Z-direction, and a length of each of the stack structures GS1 to GS3 in the Z-direction and the number of gate electrodes 230 may be substantially the same, but are not limited thereto.

The second semiconductor structure S2 may include channel studs 272 for electrical connection with the first semiconductor structure S1, an upper interconnection structure (271, 272, and 274) below the stack structures GS1, GS2, and GS3, and an upper bonding structure 280 connected to the upper interconnection structures (271, 272, and 274). The upper bonding structure 280 may be connected to the upper interconnection structure (271, 272, and 274). The upper bonding structure 280 may include an upper bonding via 281, an upper bonding pad 284, and an upper bonding insulating layer 286. The second semiconductor structure S2 may be located at substantially the same level as the channel studs 272.

The gate electrodes 230 may include at least one lower gate electrode 230L forming a gate of a ground select transistor, memory gate electrodes 230M forming a plurality of memory cells, and upper gate electrodes 230U forming gates of string select transistors. In this case, the lower gate electrode 230L and the upper gate electrodes 230U may be referred to as “lower” and “upper,” based on a direction during a manufacturing process. The number of memory gate electrodes 230M forming memory cells may be determined according to capacity of the semiconductor device 100. According to one or more embodiments, the number of the upper and lower gate electrodes 230U and 230L may be 1 to 2 or more, respectively, and the upper and lower gate electrodes 230U and 230L may have the same or different structure as the memory gate electrodes 230M.

The gate electrodes 230 may include a metal material, such as molybdenum (Mo) or tungsten (W). According to one or more embodiments, the gate electrodes 230 may include polycrystalline silicon or a metal silicide material. According to one or more embodiments, the gate electrodes 230 may further include a diffusion barrier 231, and for example, the diffusion barrier may include tungsten nitride (WN), tantalum nitride (T1N), titanium nitride (TiN), or a combination thereof.

The interlayer insulating layers 220 may be disposed between the gate electrodes 230 to form the stack structure (GS1, GS2, and GS3). The interlayer insulating layers 220 may also be disposed to be spaced apart from each other in a direction perpendicular to the lower surface of the first conductive layer 201, and may extend in the X-direction, similar to the gate electrodes 230. The interlayer insulating layers 220 may include an insulating material such as silicon oxide or silicon nitride.

In one or more embodiments, the thicknesses of the interlayer insulating layers 220 may not all be the same. For example, among the interlayer insulating layers 220, an uppermost interlayer insulating layer 222, a lowermost interlayer insulating layer 223, and an intermediate interlayer insulating layer 225 may have a greater thickness than the other interlayer insulating layers 220, but the disclosure is not limited thereto. The intermediate interlayer insulating layer 225 may be defined as interlayer insulating layers between the stack structures GS1, GS2, and GS3.

Each of the channel structures CH may have a configuration in which k channel portions CH1 to CHk (where k is 1, 2, or 3, any positive integer) penetrating k stack structures (GS1 to GSk) of the gate electrodes 230 are connected, and in one or more embodiments, the first to third channel portions CH1 to CH3 penetrating three stack structures GS1 to GS3 may be connected to each other.

As illustrated in FIG. 2, each of the first to third channel portions CH1 to CH3 may extend in a vertical direction, perpendicular to the lower surface of the first conductive layer 201, for example, in the Z-direction, and may have a pillar shape and an inclined side surface of which width decreases toward the first conductive layer 201, depending on an aspect ratio.

Lower ends of upper portions of the channel portions CH1 to CH3 and upper ends of lower portions of the channel portions CH1 to CH3 may be connected to each other to form folded portions CH_S. The folded portions CH_S may include a first channel folded portion CH_Sa between a first channel structure CH1 and a second channel structure CH2, and a second channel folded portion CH_Sb between the second channel structure CH2 and a third channel structure CH3.

As described above, the separation regions MS may be disposed to extend in the X-direction by penetrating through the gate electrodes 230.

The separation regions MS may be simultaneously formed when a channel hole is formed, without additionally performing an etching process having a high aspect ratio for forming separate separation regions MS, such that an all-in-one high aspect ratio contact (HARC) etching process is performed. Therefore, the separation region MS may include first to third separation region portions MS1, MS2, and MS3, as illustrated in FIG. 2, and each of the first to third separation region portions MS1 to MS3 may extend in a vertical direction, perpendicular to the lower surface of the first conductive layer 201, for example, in the Z-direction, and may have an inclined side surface of which width decreases toward the first conductive layer 201, according to an aspect ratio.

Lower ends of upper portions of the separation region portions MS1 to MS3 and upper ends of lower portions of the separation region portions MS1 to MS3 may be connected to each other to form folded portions MS_S. The folded portions MS_S may include a first separation region folded portion MS_Sa between a first separation region structure MS1 and a second separation region structure MS2, and a second separation region folded portion MS_Sb between the second separation region structure MS2 and a third separation region structure MS3.

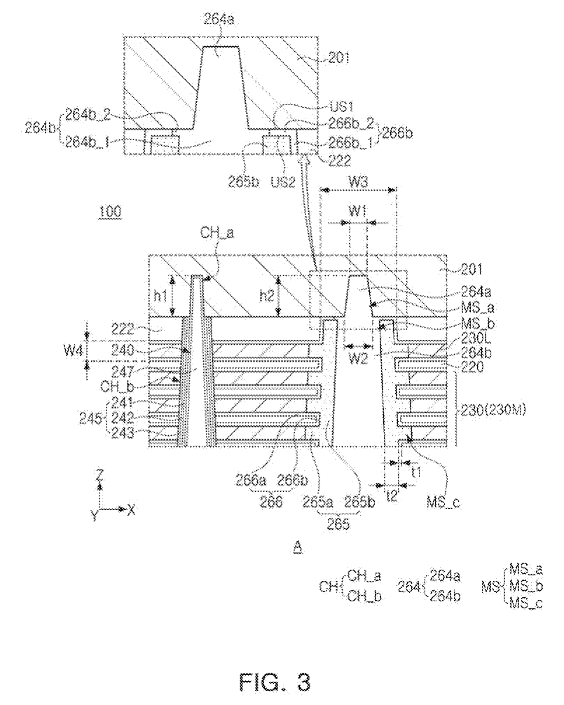

The first separation region folded portion MS_Sa may be located at substantially the same level as the first channel folded portion CH_Sa. The second separation region folded portion MS_Sb may be located at substantially the same level as the second channel folded portion CH_Sb. The separation regions MS may have an insulating layer disposed thereon, which will be described in detail in FIG. 3.

Hereinafter, the channel structures CH and the separation regions MS will be described in detail with reference to FIGS. 2 and 3.

FIG. 3 is a partially enlarged view of the semiconductor device 100 illustrated by enlarging region ”A” of FIG. 2.

Referring to FIG. 3, each of the channel structures CH may include a through portion CH_b (also referred to herein as a “channel structure through portion”) penetrating through the stack structure (GS1 to GS3), and a head portion CH_a (also referred to herein as a “channel structure head portion”) protruding above the stack structure (GS1 to GS3) and into the first conductive layer 201, respectively.

A channel layer 240 may be entirely disposed on the through portion CH_b and the head portion CH_a of the channel structure CH, and the channel layer 240 may be formed in an annular shape with a side surface surrounding a buried insulating layer 247 therein, but may also have a columnar shape such as a cylinder or a prism without the buried insulating layer 247, depending on an embodiment. The channel layer 240 may include a semiconductor material such as polycrystalline silicon or single crystal silicon, and the semiconductor material may be an undoped material or a material including a P-type impurity or an N-type impurity.

The head portion CH_a may be in direct contact with the first conductive layer 201. Therefore, as illustrated in FIG. 3, both upper and side surfaces of the channel layer 240 constituting the head portion CH_a may be covered with the first conductive layer 201.

Channel pads 249 may be disposed in a lower portion of the channel layer 240 in the channel structures CH. The channel pads 249 may be disposed to cover a lower surface of the buried insulating layer 247 and be electrically connected to the channel layer 240. The channel pads 249 may include, for example, doped polycrystalline silicon.

An information storage structure 245 may be disposed between the gate electrodes 230 and the channel layer 240. The information storage structure 245 may include a tunneling layer 241, a charge storage layer 242, and a blocking layer 243, sequentially stacked from the channel layer 240. The tunneling layer 241 may tunnel charges into the charge storage layer 242, and may include, for example, silicon oxide (SiO₂), silicon nitride (Si₃N₄), silicon oxynitride (SiON), or a combination thereof. The charge storage layer 242 may be a charge trap layer or a floating gate conductive layer. The blocking layer 243 may include silicon oxide (SiO₂), silicon nitride (Si₃N₄), silicon oxynitride (SiON), a high-κ dielectric material, or a combination thereof. According to one or more embodiments, at least a portion of the information storage structure 245 may form a channel dielectric layer extending horizontally along the gate electrodes 230.

The information storage structure 245 may be removed from the upper portion of the stack structure (GS1 to GS3) such that the head portion CH_a of the channel layer 240 may be exposed to the outside in a second portion. Therefore, a width of an upper surface of the head portion CH_a of the channel structure CH may be smaller than a width W1 of an upper surface of a head portion MS_a of the separation region (also referred to herein as a “separation region head portion”). An upper end of the information storage structure 245 may be in contact with the first conductive layer 201, and a side surface of the information storage structure 245 may be disposed to surround the channel layer 240.

The channel layer 240, the information storage structure 245, and the buried insulating layer 247 may be connected to each other between the second channel structure CH2 and the first channel structure CH1 and between the third channel structure CH3 and the second channel structure CH2.

Each of the separation regions MS may include a through portion MS_b (also referred to herein as a “separation region through portion”) penetrating through the stack structure (GS1 to GS3), at least one head portion MS_a protruding above the stack structure (GS1 to GS3) and protruding into the first conductive layer 201, and side protrusion portions MS_c protruding from a side surface of the through portion MS_b of the separation region MS toward the gate electrodes 230 and spaced apart from each other in the Z-direction.

The through portion MS_b may be a wall structure occupying most of the separation region MS, disposed to penetrate the stack structure (GS1 to GS3) in the Z-direction, and extending continuously from the first region R1, which may be a memory cell region, to the second region R2 in the X-direction. When viewed from the top, the through portion MS_b may have an elongated structure (elongate type) in which a width in the Y-direction is narrow and a width in the X-direction is long, and may have a continuous curved surface in which opposing long surfaces protrude in an outward direction. For example, it can be understood as a structure in which the shape of a hemisphere or a semi-ellipse may be continuous.

The through portion MS_b may penetrate the stack structure (GS1 to GS3) from an upper portion thereof to a lower portion thereof, and may be disposed such that an upper surface US1 is in contact with a lower surface of the first conductive layer 201, and a lower surface of the through portion MS_b is in contact with a lower surface of the lowermost interlayer insulating layer 223 of the stack structure.

The head portions MS_a may have a shape that protrudes from the upper surface US1 of the through portion MS_b into the first conductive layer 201 by a predetermined length h2. When viewed from an upper surface, each of the head portions MS_a may have a circular shape or an angular shape, and may be disposed to be spaced apart from each other in the X-direction on the protrusion portion.

For example, a plurality of head portions MS_a may be disposed in a row in an extension direction of the through portion MS_b on the through portion MS_b. It can be understood that the head portions MS_a may be disposed along a center line of a width of the through portion MS_b.

The side protrusion portions MS_c may be disposed from a long surface of a side surface of the through portion MS_b toward the gate electrode 230. Protrusion lengths of the side protrusion portions MS_c may be substantially the same, but are not limited thereto. Depending on an embodiment, the protrusion lengths may increase toward the head portion MS_a.

In each of the head portions MS_a, the width W1 of the upper surface in the X-direction may be smaller than a width W2 of a lower surface of the head portion MS_a in the X-direction, and due to a width difference, an inclined side surface may be formed between the upper surface and the lower surface. A width W3 of the upper surface US1 of the through portion MS_b in the X-direction may be at least twice the width W2 of the lower surface of the head portion MS_a in the X-direction, but the disclosure is not limited thereto. Due to a width difference between the upper surface US1 of the through portion MS_b and the lower surface of the head portion MS_a, a folded portion may be formed between the through portion MS_b and the head portion MS_a. The folded portion may be located at substantially the same level as an upper surface of the uppermost interlayer insulating layer 222 of the stack structure (GS1 to GS3).

The width W2 of the lower surface of the head portion MS_a may be less than or equal to twice a width W4 of the side protrusion portions MS_c in the Z-direction, but the disclosure is not limited thereto.

A first-side insulating layer 266b may be disposed in the through portion MS_b of the separation regions MS to have a substantially uniform side thickness t1 from an upper end to a lower end of the through portion MS_b. The first-side insulating layer 266b may be disposed between the separation regions MS and the gate electrodes 230. The first-side insulating layer 266b may be referred to as an inner side insulating layer. The first-side insulating layer 266b may include a high-κ material, and for example, aluminum oxide (Al₂O₃) or hafnium oxide (HfO₂) may be formed with the uniform thickness t1 by an atomic layer deposition (ALD) process. For example, the side thickness t1 may satisfy approximately 2 nm, but the disclosure is not limited thereto.

When viewed in the X-Z plane, the first-side insulating layer 266b may include a first portion 266b_1 disposed parallel to a side surface of the through portion MS_b, and a second portion 266b_2 extended in the X-direction parallel to the upper surface US1 of the through portion MS_b by bending the first-side insulating layer 266b at substantially the same level as the upper surface of the uppermost interlayer insulating layer 222 of the stack structure (GS1 to GS3). The second portion 266b_2 of the first-side insulating layer 266b may be disposed on a portion of the upper surface US1 of the through portion MS_b, and may be in contact with the first conductive layer 201.

A second-side insulating layer 265b surrounding an inner side surface of the first-side insulating layer 266b may be disposed in the through portion MS_b to have a uniform thickness t2. The second-side insulating layer 265b may include an insulating material, and may include, for example, silicon oxide, silicon nitride, or silicon oxynitride. The side thickness t2 of the second-side insulating layer 265b may be greater than the side thickness t1 of the first-side insulating layer 266b. For example, the side thickness t2 may be approximately 25 nm to 35 nm by an atomic layer deposition (ALD) process, but the disclosure is not limited thereto.

A buried insulating layer 264 may include a lower buried insulating layer 264b disposed in the through portion MS_b, and an upper buried insulating layer 264a in which the lower buried insulating layer 264b extends in the Z-direction and protrudes into an internal portion of the first conductive layer 201 to form the head portion MS_a.

The buried insulating layer 264 may be formed by a chemical vapor deposition (CVD) method, may include an insulating material, and may include, for example, silicon oxide, silicon nitride, or silicon oxynitride. The second-side insulating layer 265b and the buried insulating layer 264 may include different materials.

The lower buried insulating layer 264b may be disposed on the second-side insulating layer 265b. When viewed in the X-Z plane, the lower buried insulating layer 264b may include a first portion 264b_1 contacting a side surface of the second-side insulating layer 265b, and a second portion 264b_2 bent along an upper surface US2 of the second-side insulating layer 265b and protruding in the X-direction. The second portion 264b_2 may be disposed on a portion of the upper surface US1 of the through portion MS_b to contact the first conductive layer 201, and may be in contact with the side surface of the second portion 266b_2 of the first-side insulating layer 266b.

Therefore, the upper surface US2 of the second-side insulating layer 265b may be in contact with the second portion 266b_2 of the first-side insulating layer and the second portion 264b_2 of the lower buried insulating layer 264b. The upper surface US2 of the second-side insulating layer 265b may be located at a level lower than the upper surface US1 of the through portion MS_b, and may be spaced apart from the upper surface US1 of the through portion MS_b.

Since the head portion MS_a of the separation regions MS may be in direct contact with the first conductive layer 201, both the upper surface and the side surface of the upper buried insulating layer 264a constituting the head portion MS_a may be in contact with the first conductive layer 201. Therefore, the conductive material remaining in the head portion MS_a may be removed, and the upper buried insulating layer 264a may be buried in the head portion MS_a, thereby preventing leakage current generated when the conductive material remaining in the head portion MS_a is in contact with the first conductive layer 201, and preventing defects generated when the remaining conductive material 230R is separated from the separation regions MS during the process.

The height h2 of the separation regions MS in the Z-direction from the lower surface of the first conductive layer 201 of the head portion MS_a may be substantially the same as the height h1 of the channel structures CH in the Z-direction from the lower surface of the first conductive layer 201 of the head portion CH_a.

Each of the side protrusion portions MS_c of the separation regions MS may include a first horizontal insulating layer 265a in which the second-side insulating layer 265b is bent toward the gate electrodes 230 to extend in the X-direction. The first horizontal insulating layer 265a may be located at the same level as the gate electrodes 230, and may have a thickness, equal to a thickness of each of the gate electrodes 230 in the Z-direction. For example, the thickness may be 20 nm to 25 nm, but the disclosure is not limited thereto. The first horizontal insulating layers 265a may be in contact with the side surfaces of the gate electrodes 230 to protect the gate electrodes 230. The first horizontal insulating layer 265a may have a length of 20 nm to 25 nm in the X-direction, but the disclosure is not limited thereto.

Each of the side protrusion portions MS_c of the separation regions MS may include a second horizontal insulating layer 266a in which the first-side insulating layer 266b is bent along and generally conforms to the first horizontal insulating layer 265a and extends in the X-direction to be disposed on the upper and lower surfaces of the first horizontal insulating layer 265a (e.g., the second horizontal insulating layer is in contact with an upper surface of the first horizontal insulating layer of a first side protrusion portion among the side protrusion portions and is in contact with a lower surface of a second side protrusion portion among the side protrusion portions, where the first side protrusion portion is adjacent to the second side protrusion portion in the Z-direction). The second horizontal insulating layer 266a may also be disposed on the upper and lower surfaces of the gate electrodes 230 in the stack structure (GS1 to GS3). The second horizontal insulating layer 266a may function as a gate dielectric layer to minimize electrical interference between the gate electrodes 230. The second horizontal insulating layers 266a may be formed to have a uniform thickness t1 the same as the first-side insulating layer 266b. For example, the side thickness t1 may be approximately 2 nm, but the disclosure is not limited thereto.

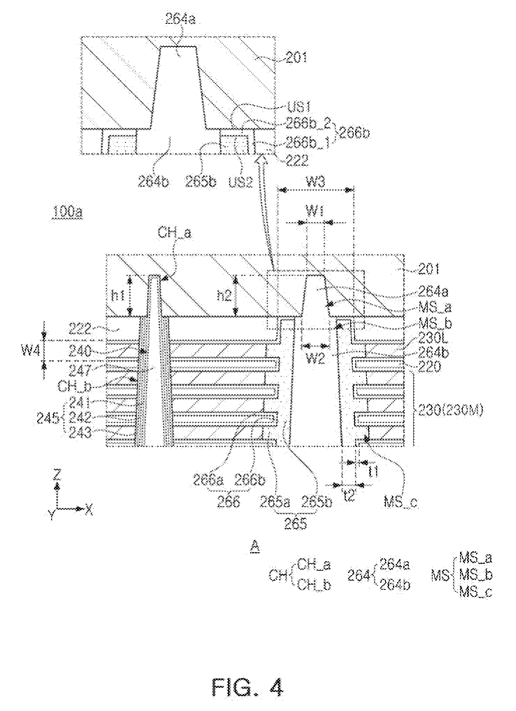

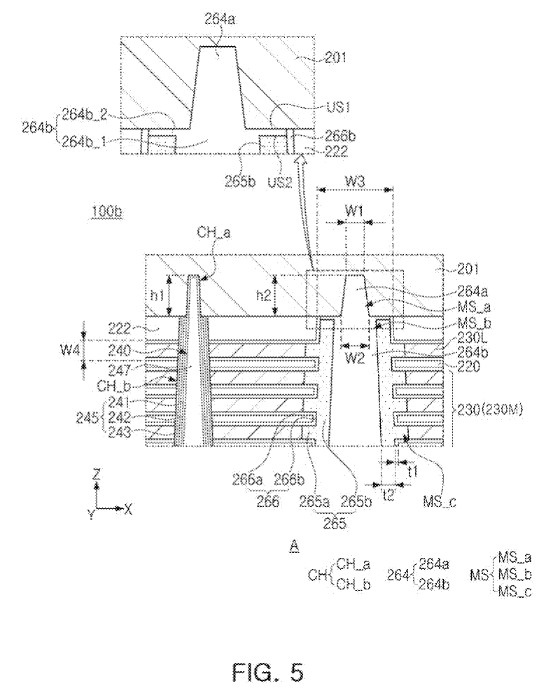

Hereinafter, one or more embodiments will be described with reference to FIGS. 4-6. FIGS. 4 and 5 are partially enlarged views of a semiconductor device according to one or more embodiments, illustrated by enlarging region ‘A’ of FIG. 2.

Referring to FIG. 4, a semiconductor device 100a may be identical to the semiconductor device 100 of FIGS. 1-3, except for a first-side insulating layer 266b and a lower buried insulating layer 264b on an upper end of a through portion MS_b.

Specifically, when viewed in the XY plane, the first-side insulating layer 266b may include a first portion 266b_1 disposed parallel to a side surface of the through portion MS_b, and a second portion 266b_2 bent at substantially the same level as an upper surface of an uppermost interlayer insulating layer 222 of a stack structure (GS1 to GS3) and extended in the X-direction parallel to an upper surface US1 of the through portion MS_b. The second portion 266b_2 of the first-side insulating layer 266b may extend to contact a side surface of the lower buried insulating layer 264b. Therefore, an upper surface US2 of a second-side insulating layer 265b may be in entire contact with the first-side insulating layer, but the disclosure is not limited thereto.

The lower buried insulating layer 264b may be disposed on the second-side insulating layer 265b, and may be in contact with a side surface of the second-side insulating layer 265b, and may fill an internal space of the through portion MS_b. The lower buried insulating layer 264b may be in contact with the second portion 266b_2 of the first-side insulating layer 266b, and the lower buried insulating layer 264b may be in contact with a first conductive layer 201.

Referring to FIG. 5, a semiconductor device 100b may be identical to the semiconductor device 100 of FIGS. 1-3, except for a first-side insulating layer 266b and a lower buried insulating layer 264b on an upper end of a through portion MS_b.

The first-side insulating layer 266b may not be folded to the upper end of the through portion MS_b, and when viewed in the XY plane, may extend to be parallel to a side surface of the through portion MS_b to be in contact with a first conductive layer 201.

When viewed in the XY plane, the lower buried insulating layer 264b may include a first portion 264b_1 contacting a side surface of a second-side insulating layer 265b, and a second portion 264b_2 folded along an upper surface US2 of the second-side insulating layer 265b and protruding in the X-direction. The second portion 264b_2 of the lower buried insulating layer 264b may be disposed on a portion of an upper surface US1 of the through portion MS_b to contact the first conductive layer 201, and may extend to contact the first-side insulating layer 266b. Therefore, the upper surface US2 of the second-side insulating layer 265b may be in entire contact with the second portion 264b_2 of the lower buried insulating layer 264b, but the disclosure is not limited thereto.

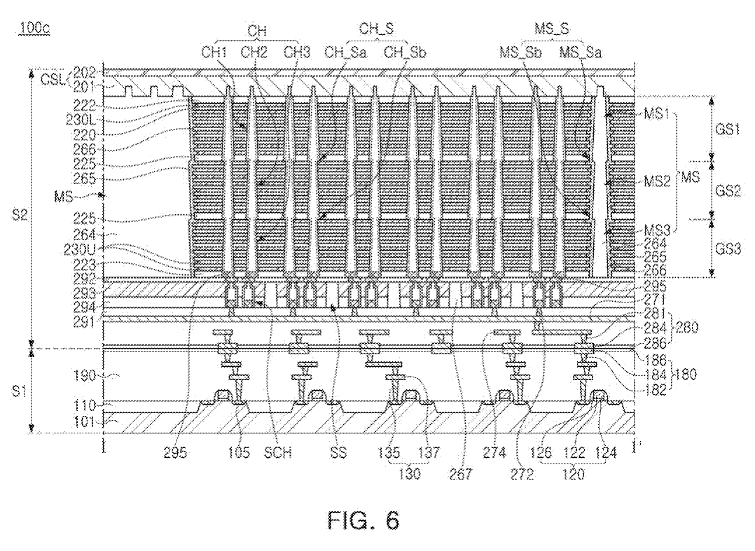

FIG. 6 is a schematic cross-sectional view of a semiconductor device according to one or more embodiments. A semiconductor device 100c of FIG. 6 may be identical to the semiconductor device 100 of FIGS. 1-3, except that second channel structures SCH is included on channel structures CH.

The second channel structures SCH may penetrate an upper gate electrode 293 to extend in the Z-direction, and may be connected to the channel structures CH, respectively. The second channel structures SCH may be respectively disposed on the channel structures CH, and may be disposed to be shifted in a horizontal direction from the channel structures CH, but the disclosure is not limited thereto.

A horizontal insulating layer 292 may be disposed between the channel structures CH and the second channel structures SCH, and may extend horizontally. The horizontal insulating layer 292 may be disposed between the upper gate electrode 293 and a lowermost interlayer insulating layer 223. The horizontal insulating layer 292 may be used as an etching stop layer when forming the second channel structures SCH, and may also be used when forming connection pads 295.

The horizontal insulating layer 292 may include an insulating material, and may include a different material from the lowermost interlayer insulating layer 223. The horizontal insulating layer 292 may be a hydrogen blocking layer, and may include a material blocking or reducing diffusion of hydrogen (H). The horizontal insulating layer 292 may include a nitride, and may include, for example, at least one of SiN, SiON, SiCN, or SiOCN.

The connection pads 295 may penetrate the horizontal insulating layer 292 between the channel structures CH and the second channel structures SCH to electrically connect the first channel layers and the second channel layers. The connection pads 295 may be formed by removing a portion of the horizontal insulating layer 292, and may have upper surfaces coplanar with an upper surface of the horizontal insulating layer 292. The connection pads 295 may be disposed in a configuration in which a channel pad 249 is partially recessed. Specific arrangement of the connection pads 295 may be variously changed in embodiments. The connection pads 295 may include a conductive material, and may include, for example, polycrystalline silicon.

The upper gate electrode 293 may be disposed on the X-Y plane, and may include a conductive material. The upper gate electrode 293 may include the same material as gate electrodes 230, but may include doped polysilicon, unlike this.

Insulating regions SS may include an upper separation insulating layer 267, respectively. The upper separation insulating layer 267 may include an insulating material, and may include, for example, silicon oxide, silicon nitride, or silicon oxynitride.

A second horizontal insulating layer 294 may be disposed to cover the upper gate electrode 293. The second horizontal insulating layer 294 may be disposed on the horizontal insulating layer 292, and may cover upper and side surfaces of the upper gate electrode 293. A first capping insulating layer 291 may be disposed below the second horizontal insulating layer 294, and the first capping insulating layer 291 and the second horizontal insulating layer 294 may be formed of an insulating material, and may be formed as a plurality of insulating layers.

The second channel structures SCH may include a second channel layer, a second gate dielectric layer, a second channel buried insulating layer, and a second channel pad, disposed in an upper channel hole, respectively. The second channel layer may be formed in an annular shape surrounding the second channel buried insulating layer therein. The second channel layer may be connected to the connection pad 295 in a lower portion, and may be electrically connected to a channel layer 240 of the channel structure CH through the connection pad 295.

Descriptions of materials of the second channel layer, the second gate dielectric layer, the second channel buried insulating layer, and the second channel pad may be equally applied to the descriptions of the channel layer 240, the information storage structure 245, the channel buried insulating layer 247, and the channel pad 249, described above.

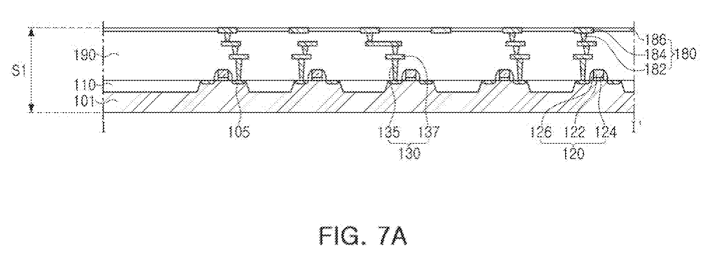

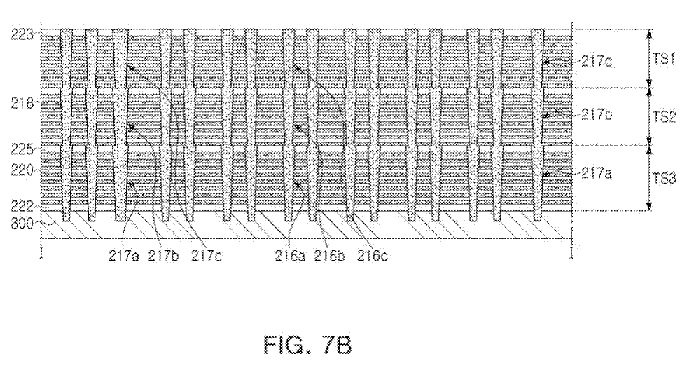

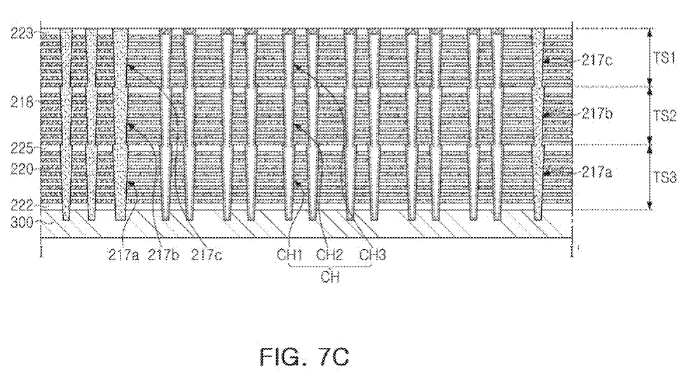

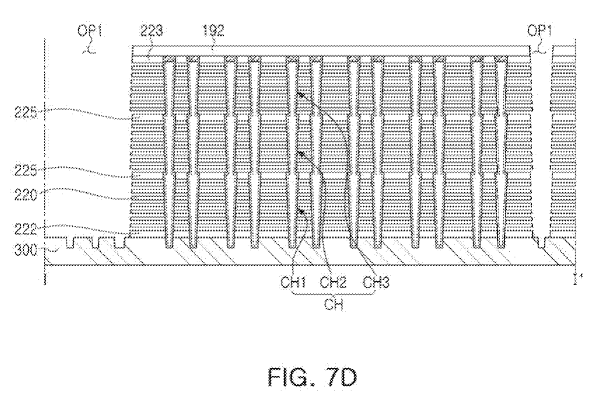

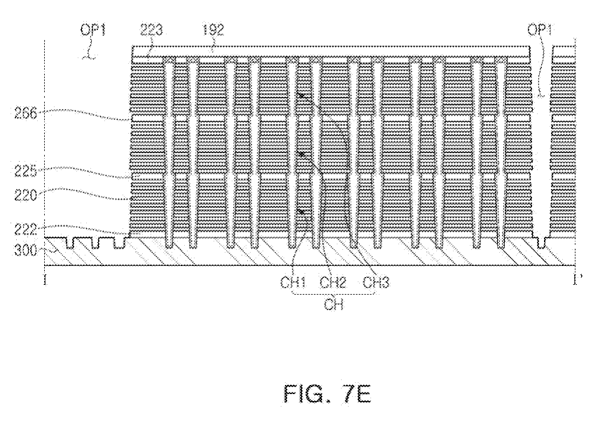

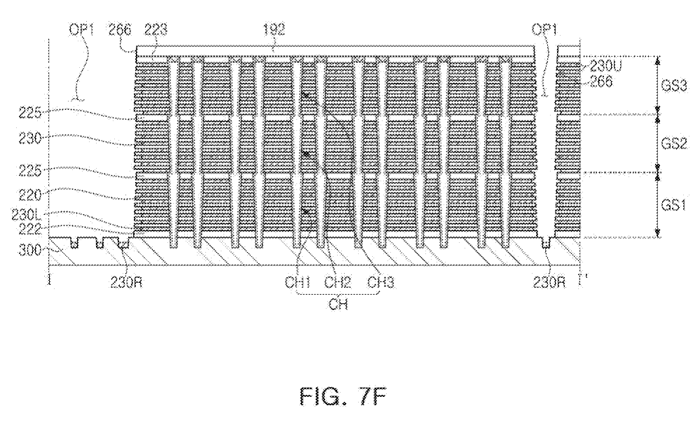

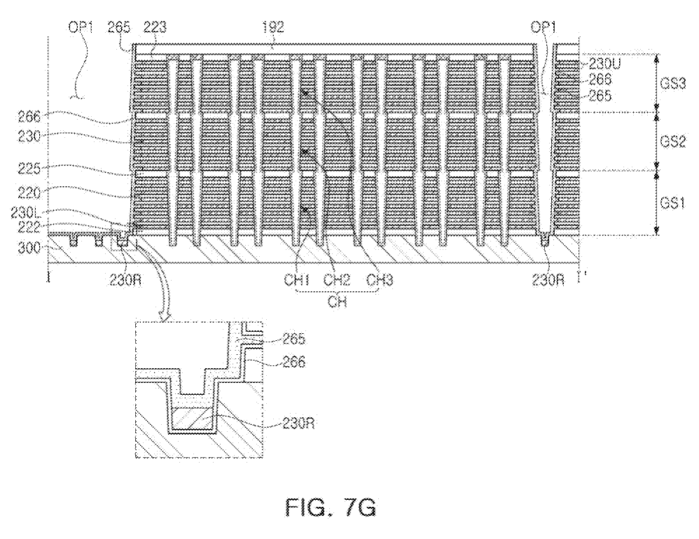

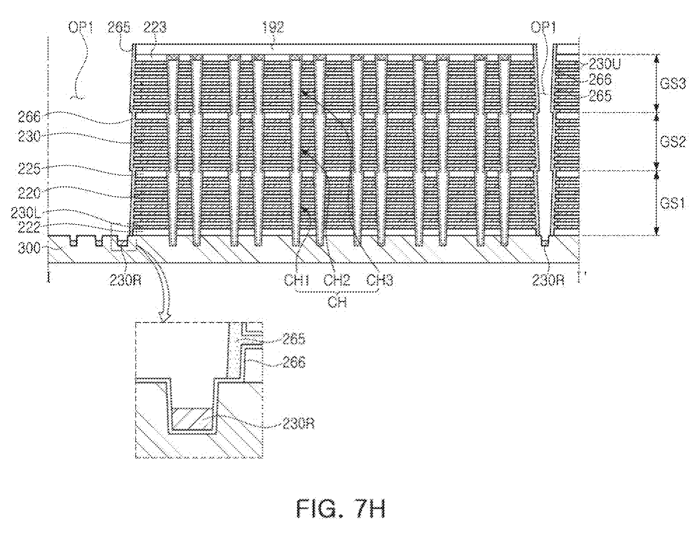

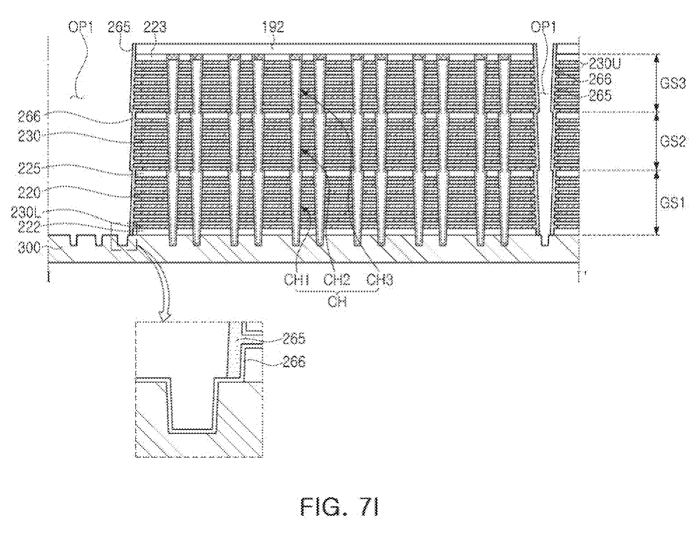

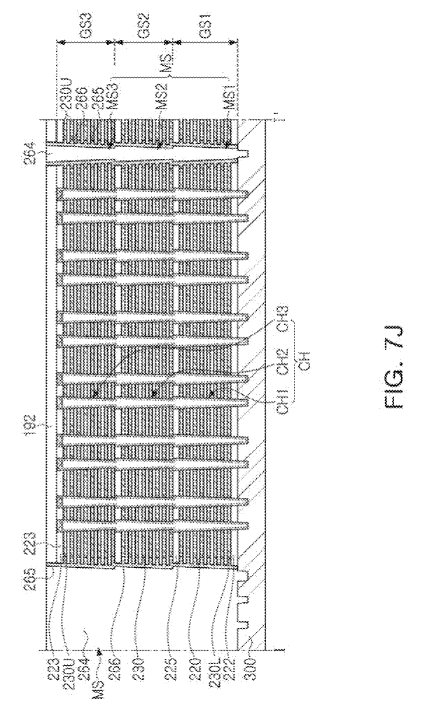

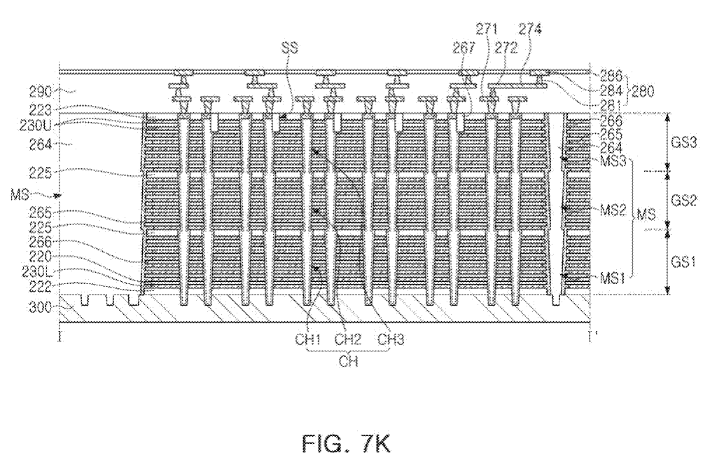

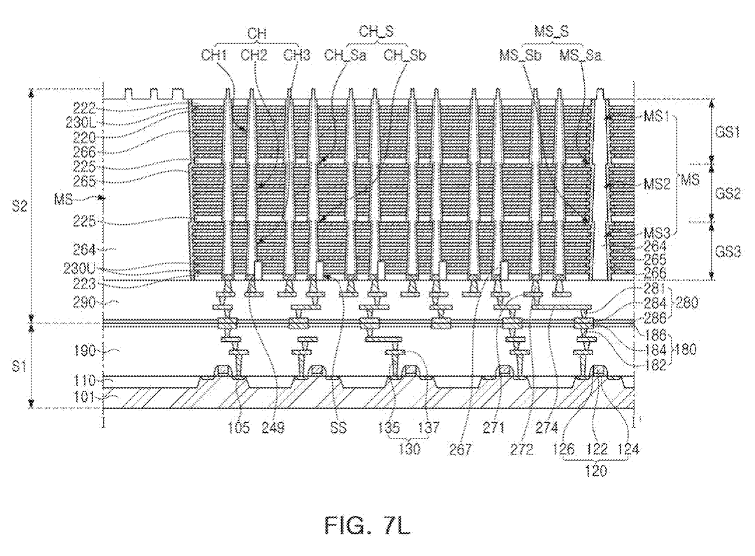

FIGS. 7A-7L are schematic cross-sectional views illustrating a method of manufacturing a semiconductor device according to one or more embodiments.

Referring to FIG. 7A, a first semiconductor structure S1 (PERI) including circuit elements 120, a lower interconnection structure 130, a lower bonding structure 180, and a lower capping layer 190 forming a peripheral circuit region PERI may be formed on a first substrate 101.

First, element isolation layers 110 may be formed in a first substrate 101, and a circuit gate dielectric layer 122 and a circuit gate electrode 124 may be sequentially formed on the first substrate 101. The element isolation layers 110 may be formed, for example, by a shallow trench isolation (STI) process. The circuit gate dielectric layer 122 may be formed on the first substrate 101, and the circuit gate electrode 124 may be formed on the circuit gate dielectric layer 122. The circuit gate dielectric layer 122 and the circuit gate electrode 124 may be formed using atomic layer deposition (ALD) or chemical vapor deposition (CVD). The circuit gate dielectric layer 122 may be formed of silicon oxide, and the circuit gate electrode 124 may be formed of at least one of polycrystalline silicon or a metal silicide layer, but are not limited thereto. Next, spacer layers 126 may be formed on both sidewalls of the circuit gate dielectric layer 122 and the circuit gate electrode 124, and impurities may be injected into an active region of the first substrate 101 on both sides of the circuit gate electrode 124 to form source/drain regions 105.

Among lower interconnection structures 130, lower contact plugs 135 may be formed by forming a portion of a lower capping layer 190, etching a portion to remove the same, and filling a conductive material therein. Lower interconnection lines 137 may be formed, for example, by depositing a conductive material, and patterning the same.

Among lower bonding structures 180, lower bonding vias 182 may be formed by forming a portion of the lower capping layer 190, etching a portion to remove the same, and filling a conductive material therein. Lower bonding pad 184 may be formed, for example, by depositing a conductive material, and patterning the same. The lower bonding structures 180 may be formed, for example, by a deposition process or a plating process. A lower bonding insulating layer 186 may be formed by covering a portion of upper and side surfaces of the lower bonding pad 184, and then performing a planarization process until the upper surface of the lower bonding pad 184 is exposed.

The lower capping layer 190 may be formed as a plurality of insulating layers. The lower capping layer 190 may be a portion in each operation of forming the lower interconnection structure 130 and the lower bonding structure 180. As a result, a first semiconductor structure S1, which may be a peripheral circuit region PERI, may be formed.

Referring to FIG. 7B, a process of manufacturing a second semiconductor structure S2 (CELL) may begin. On a base substrate 300 (SUB), sacrificial insulating layers 218 and interlayer insulating layers 220 may be alternately stacked to form a mold structure (TS1, TS2, and TS3), and sacrificial vertical structures 216a, 216b, 216c, 217a, 217b, and 217c may be formed at positions in which each vertical structure is formed, respectively.

A first mold structure TS1 may be formed on the base substrate 300 at a height at which first channel structures CH1 (see FIG. 3) are disposed. The base substrate 300 may include a semiconductor material, for example, a group IV semiconductor, a group III-V compound semiconductor, or a group II-VI compound semiconductor.

The sacrificial insulating layers 218 may be layers in which at least a portion is replaced with a portion of the gate electrodes 230 through a subsequent process. The sacrificial insulating layers 218 may be formed of a different material from the interlayer insulating layers 220. For example, the interlayer insulating layer 220 and uppermost, intermediate, and lowermost interlayer insulating layers 222, 223, and 225 may be formed of at least one of silicon oxide or silicon nitride, and the sacrificial insulating layers 218 may be formed of a different material from the interlayer insulating layer 220 selected from silicon, silicon oxide, silicon carbide, or silicon nitride. In embodiments, thicknesses of the interlayer insulating layers 220 may not be all the same. In addition, thicknesses of the interlayer insulating layers 220 and thicknesses of the sacrificial insulating layers 218, and the number of films constituting them may be changed from those illustrated.

The interlayer insulating layers 220 and the sacrificial insulating layers 218 forming the first mold structure TS1 may be alternately stacked on the base substrate 300.

First vertical sacrificial layers 216a may be formed at positions corresponding to lower portions of first channel structures CH1. The first vertical sacrificial layers 216a may be formed by forming holes to penetrate the first mold structure TS1, depositing a sacrificial layer material in the holes, and performing a planarization process. When forming the holes, a plurality of separation holes spaced apart from each other may be formed in a region corresponding to a separation region MS, and a first separation sacrificial layer 217a filling the plurality of separation holes may be formed together. Vertical sacrificial layers including the first vertical sacrificial layers 216a and the first separation sacrificial layers 217a may include, for example, at least one of TiN or polycrystalline silicon.

Next, a second mold structure TS2 may be formed in the same manner as the first mold structure TS1, and a high aspect ratio contact (HARC) etching penetrating through the second mold structure TS2 may be performed, and a second vertical sacrificial layer 216b and a second separation sacrificial layer 217b may be formed. A third mold structure TS3, a third vertical sacrificial layer 216c, and a third separation sacrificial layer 217c may be formed in the same manner.

Therefore, all of the vertical structures, channel structures CH, and the plurality of vertical sacrificial layers 216a, 216b, 216c, 217a, 217b, and 217c forming the separation regions MS of FIG. 2 may be formed simultaneously.

Referring to FIG. 7C, the channel structures CH penetrating through the mold structures TS1 to TS3 of the sacrificial insulating layers 218 and the interlayer insulating layers 220 may be formed on the base substrate 300.

The channel structures CH may be formed by forming upper holes on the vertical sacrificial layers 216a, 216b, and 216c, then removing the vertical sacrificial layers 216a, 216b, and 216c, to form channel holes having a hole shape, and filling the channel holes as a plurality of layers. The plurality of layers may include an information storage structure 245, a channel layer 240, a filling insulating layer 247, and a channel pad 249.

Due to heights of the mold structures TS1 to TS3, sidewalls of the channel structures CH may not be perpendicular to an upper surface of the base substrate 300. The channel structures CH may be formed to recess a portion of the base substrate 300, depending on depths of the channel holes.

Referring to FIG. 7D, an upper insulating layer 192 may be formed on the mold structure and the lowermost (uppermost in a process) interlayer insulating layer 223, and an opening may be formed in the upper insulating layer 192. Through the opening, the separation sacrificial layers 217a, 217b, and 217c filling separation holes formed at positions of the separation regions MS may be removed, and the separation holes may be expanded and connected to each other through cleaning or the like, thereby forming a separation region opening OP1 connected to each other in the X-direction, as illustrated in FIG. 1. A side surface forming the separation region MS may have a shape in which a convex curve continues outwardly as a plurality of separation holes are expanded in a circumferential direction, but the disclosure is not limited thereto. A region in which the extended separation region opening OP1 penetrates the mold structure (TS1 to TS3) may have a shape corresponding to the through portion MS_b of the separation region in FIG. 3, and a region in which the base substrate 300 penetrates may have a shape corresponding to the head portion MS_a of the separation region in FIG. 3. The sacrificial insulating layers 218 may be selectively removed with respect to the interlayer insulating layers 220 through wet etching in the separation region opening OP1.

Referring to FIG. 7E, a first insulating layer 266 may be formed by depositing a high-κ material in regions in which the sacrificial insulating layers 218 are removed through the separation region opening OP1, and in the separation region opening OP1. Specifically, a second horizontal insulating layer 266a may be formed between regions in which the sacrificial insulating layers 218 are removed and the interlayer insulating layers 220 in a direction, parallel to the upper surface of the base substrate 300, and a first-side insulating layer 266b may be formed on a side surface of the separation region opening OP1. The first insulating layer 266 may also be deposited on a lower surface of the separation region opening OP1, but may be partially removed through a subsequent etching process, as illustrated in FIG. 7J. The first insulating layer 266 may be formed to a uniform thickness using an atomic layer deposition (ALD) process. For example, the first insulating layer 266 may include at least one of aluminum oxide (Al₂O₃) or hafnium oxide (HfO₂), but the disclosure is not limited thereto.

Referring to FIG. 7F, gate electrodes 230 may be formed by depositing a conductive material in regions in which the sacrificial insulating layers 218 are removed through the separation region opening OP1. The conductive material may include a metal, polycrystalline silicon, or a metal silicide material. When the gate electrodes 230 are all formed by depositing the conductive material, conductive materials remaining in the separation region opening OP1 may be removed.

In this case, a portion of the gate electrodes 230 may be removed in a region contacting a side surface of the separation region opening OP1, and such a space may have a shape corresponding to the separation region side protrusion portion MS_c of FIG. 3. When all the conductive materials remaining in the separation region opening OP1 are removed and the separation region opening OP1 is exposed, conductive materials 230R identical to the gate electrodes 230 may remain in a region corresponding to the head portion MS_a of the separation region in FIG. 3 due to a narrow width.

Referring to FIG. 7G, a second insulating layer 265 may be formed by depositing an insulating material through the separation region opening OP1. Specifically, a first horizontal insulating layer 265a may be formed between the interlayer insulating layers 220 in a region in which the gate electrodes 230 are not formed among regions in which the sacrificial insulating layers 218 are removed. A second-side insulating layer 265b may be formed on a side surface of the separation region opening OP1. The second insulating layer 265 may be deposited on a lower surface of the separation region opening OP1, but may be removed through a subsequent etching process, as illustrated in FIG. 7H. The second insulating layer 265 may be formed with a uniform thickness using an insulating material such as silicon oxide or silicon nitride using an atomic layer deposition (ALD) process. The first horizontal insulating layer 265a may protect the gate electrodes 230 while contacting side surfaces of the gate electrodes 230.

Referring to FIG. 7H, the second insulating layer 265 deposited on the lower surface of the separation region opening OP1 may be removed through an etching back process. Therefore, in a region corresponding to the head portion MS_a of the separation region in FIG. 3 in the separation region opening OP1, the second insulating layer 265 may be completely removed, and the second insulating layer 265 may include the second-side insulating layer 265b and the first horizontal insulating layer 265a. A process of removing the second insulating layer 265 may not be limited to the etching back process, and may be performed by various etching processes.

Referring to FIG. 7I, the conductive material 230R remaining in the separation region opening OP1 may be removed by an etching process such as wet etching and/or dry etching. Therefore, as illustrated in FIG. 7L, when the first semiconductor structure S1 and the second semiconductor structure S2 are joined and lower ends of the channel structures CH and lower ends of the separation regions MS are exposed after the base substrate 300 is removed (see FIG. 7l), leakage current caused when the conductive material 230R remaining in the head portion MS_a of the separation regions is in contact with the first conductive layer 201 may be prevented, and defects caused when the remaining conductive material 230R is separated from the separation regions MS during the process may be prevented.

Referring to FIG. 7J, the first insulating layer 266 deposited on the lower surface of the separation region opening OP1 may be removed by an etching process such as wet etching and/or dry etching. Therefore, the first insulating layer 266 may be completely removed in a region corresponding to the head portion MS_a of the separation region in FIG. 3, in the separation region opening OP1. Referring to FIG. 3, the first portion 266b_1 of the first-side insulating layer 266b may be protected by the second-side insulating layer 265b, and may thus not be removed, and the second portion 266b_2 of the first-side insulating layer 266b may be also not completely removed by the second-side insulating layer 265b, and may remain partially.

After the etching process, the buried insulating layer 264 may be buried through the separation region opening OP1 to form separation regions MS. The buried insulating layer 264 may be formed using chemical vapor deposition (CVD). The buried insulating layer 264 may be formed of at least one of silicon oxide and silicon nitride, and may be a different material from the second insulating layer 265.

Referring to FIG. 7K, insulating regions SS crossing an upper gate electrode 230U may be formed, upper interconnection structures 271 and 272 including channel studs 272 and upper interconnections 271 may be formed, and an upper bonding structure 280 may be formed.

Upper interconnection structures 271, 272, and 274 may be formed by stacking a diffusion barrier and a conductive material. The upper bonding structure 280 may be formed on the upper interconnection structures 271, 272, and 274.

The upper bonding structure 280 may be formed in a similar manner to forming the lower bonding structure 180. By doing so, the second semiconductor structure S2, which may be a memory cell structure CELL, may be formed. During the manufacturing process of the semiconductor device 100, the second semiconductor structure S2 may further include the base substrate 300.

Referring to FIG. 7L, the first semiconductor structure S1, which may be a peripheral circuit structure PERI, and the second semiconductor structure S2, which may be a memory cell structure CELL, may be joined.

The first semiconductor structure S1 and the second semiconductor structure S2 may be connected by bonding a lower bonding pad 184 and an upper bonding pad 284 by applying pressure. A lower bonding insulating layer 186 and an upper bonding insulating layer 286 may be connected by bonding them by applying pressure. The second semiconductor structure S2 may be joined on the first semiconductor structure S1 with the upper bonding pad 284 facing downward. The first semiconductor structure S1 and the second semiconductor structure S2 may be directly bonded without intervention of an adhesive such as a separate adhesive layer.

With the first semiconductor structure S1 and the second semiconductor structure S2 joined, the base substrate 300 exposed to an upper portion of the second semiconductor structure S2 may be removed, and a lower end of the channel structures CH may be exposed. In this case, the information storage structure 245 on the second portion of the exposed channel structure CH may be removed. The information storage structure 245 may be removed by a photolithography process and an etching process such as wet etching and/or dry etching. Due to this, the channel layer 240 of the channel structure CH protruding over the stack structures GS1, GS2, and GS3 may be exposed, such that the head portion CH_a of the channel structure CH is disposed. Therefore, the channel layer 240 of the head portion CH_a may be in direct contact with a first conductive layer 201.

Next, as illustrated in FIG. 2, the first conductive layer 201 may be formed to entirely cover a first region R1, which may be a cell region. The first conductive layer 201 may be formed by depositing a semiconductor layer, specifically, a crystalline silicon layer, for example, a polycrystalline silicon layer. The first conductive layer 201 may be formed to have a bend along the protruding channel structures CH, but may be formed to have a predetermined thickness such that an upper surface may be flat. A second conductive layer 202 may be formed on the first conductive layer 201. Specifically, the second conductive layer 202 may be formed as a plurality of layers. A buffer layer may be formed conformally to entirely cover the second conductive layer 202, and an oxide film, for example, a silicon oxide film or the like, may be formed as the buffer layer.

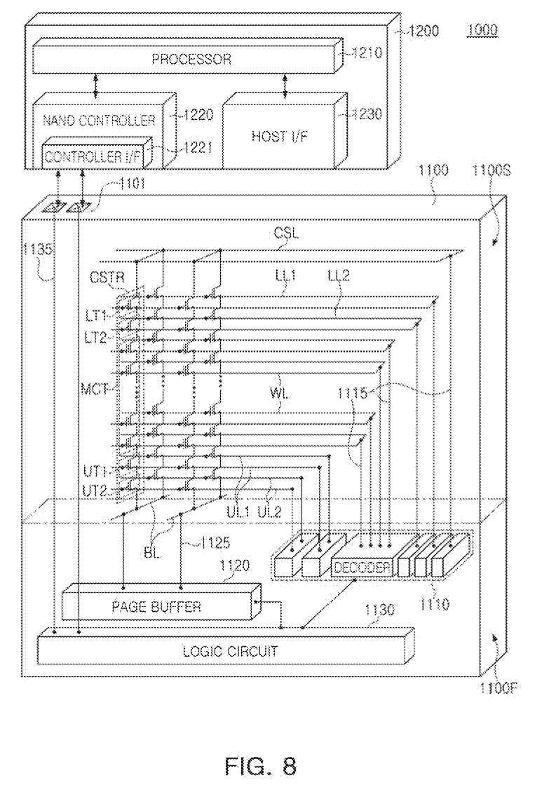

FIG. 8 is a view schematically illustrating a data storage system including a semiconductor device according to one or more embodiments.

Referring to FIG. 8, a data storage system 1000 may include a semiconductor device 1100 and a controller 1200 electrically connected to the semiconductor device 1100. The data storage system 1000 may be a storage device including one or more semiconductor devices 1100 or an electronic device including a storage device. For example, the data storage system 1000 may be a solid state drive device (SSD), a universal serial bus (USB), a computing system, a medical device, or a communication device including one or more semiconductor devices 1100.

The semiconductor device 1100 may be a non-volatile memory device, and may be, for example, a NAND flash memory device as described above with reference to FIGS. 1-6. The semiconductor device 1100 may include a first semiconductor structure 1100F and a second semiconductor structure 1100S on the first semiconductor structure 1100F. According to one or more embodiments, the first semiconductor structure 1100F may be disposed next to the second semiconductor structure 1100S. The first semiconductor structure 1100F may be a peripheral circuit structure including a decoder circuit 1110, a page buffer 1120, and a logic circuit 1130. The second semiconductor structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second semiconductor structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be changed depending on embodiments.

According to one or more embodiments, the upper transistors UT1 and UT2 may include string select transistors, and the lower transistors LT1 and LT2 may include ground select transistors. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

According to one or more embodiments, the lower transistors LT1 and LT2 may include ground select transistors LT1 and LT2 connected in series. The upper transistors UT1 and UT2 may include string select transistors UT1 and UT2.

The common source line CSL, the first and second gate lower lines LL1 and LL2, the word lines WL, and the first and second gate upper lines UL1 and UL2 may be electrically connected to the decoder circuit 1110 through first connection wires 1115 extending from the first semiconductor structure 1100F to the second semiconductor structure 1100S. The bit lines BL may be electrically connected to the page buffer 1120 through second connection wires 1125 extending from the first semiconductor structure 1100F to the second semiconductor structure 1100S.

In the first semiconductor structure 1100F, the decoder circuit 1110 and the page buffer 1120 may perform a control operation for at least one select memory cell transistor among the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connection wire 1135 extending from the first semiconductor structure 1100F to the second semiconductor structure 1100S.

The controller 1200 may include a processor 1210, a NAND controller 1220, and a host interface 1230. According to embodiments, the data storage system 1000 may include a plurality of semiconductor devices 1100, and in this case, the controller 1200 may control the plurality of semiconductor devices 1100.

The processor 1210 may control the overall operation of the data storage system 1000, including the controller 1200. The processor 1210 may operate according to a predetermined firmware, and may control the NAND controller 1220 to access the semiconductor device 1100. The NAND controller 1220 may include a NAND interface 1221 processing communication with the semiconductor device 1100. Through the NAND interface 1221, a control command for controlling the semiconductor device 1100, data to be written to the memory cell transistors MCT of the semiconductor device 1100, data to be read from the memory cell transistors MCT of the semiconductor device 1100, or the like may be transmitted. The host interface 1230 may provide a communication function between the data storage system 1000 and an external host. When the control command is received from the external host through the host interface 1230, the processor 1210 may control the semiconductor device 1100 in response to the control command.

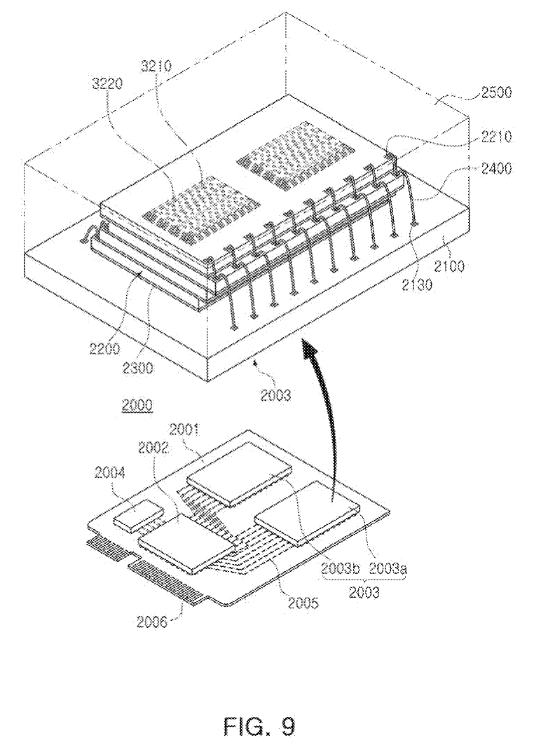

FIG. 9 is a perspective view schematically illustrating a data storage system including a semiconductor device according to one or more embodiments.

Referring to FIG. 9, a data storage system 2000 according to one or more embodiments may include a main board 2001, a controller 2002 mounted on the main board 2001, one or more semiconductor packages 2003, and a DRAM 2004. The semiconductor package 2003 and the DRAM 2004 may be connected to the controller 2002 by wiring patterns 2005 formed on the main board 2001.

The main board 2001 may include a connector 2006 including a plurality of pins coupled to an external host. The number and arrangement of the plurality of pins in the connector 2006 may be changed depending on a communication interface between the data storage system 2000 and the external host. According to one or more embodiments, the data storage system 2000 may communicate with the external host, according to any one of interfaces such as a universal serial bus (USB), a peripheral component interconnect express (PCI-Express), a serial advanced technology attachment (SATA), an M-Phy for universal flash storage (UFS), or the like. According to one or more embodiments, the data storage system 2000 may operate by power supplied from the external host through the connector 2006. The data storage system 2000 may further include a power management integrated circuit (PMIC) distributing the power supplied from the external host to the controller 2002 and the semiconductor package 2003.

The controller 2002 may write data to the semiconductor package 2003 or read data from the semiconductor package 2003, and may improve an operating speed of the data storage system 2000.

The DRAM 2004 may be a buffer memory for mitigating a speed difference between the semiconductor package 2003, which may be a data storage space, and the external host. The DRAM 2004 included in the data storage system 2000 may also function as a type of cache memory, and may also provide a space for temporarily storing data in a control operation for the semiconductor package 2003. When the data storage system 2000 includes the DRAM 2004, the controller 2002 may further include a DRAM controller for controlling the DRAM 2004 in addition to a NAND controller for controlling the semiconductor package 2003.

The semiconductor package 2003 may include first and second semiconductor packages 2003a and 2003b spaced apart from each other. The first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on the lower surface of each of the semiconductor chips 2200, a connection structure 2400 electrically connecting the semiconductor chips 2200 and the package substrate 2100, and a molded layer 2500 covering the semiconductor chips 2200 and the connection structure 2400 on the package substrate 2100.

The package substrate 2100 may be a printed circuit board including package upper pads 2130. Each semiconductor chip 2200 may include an input/output pad 2210. The input/output pad 2210 may correspond to the input/output pad 1101 of FIG. 8. Each of the semiconductor chips 2200 may include gate stack structures 3210 and channel structures 3220. Each of the semiconductor chips 2200 may include the semiconductor device described above with reference to FIGS. 1-6.

According to one or more embodiments, the connection structure 2400 may be a bonding wire electrically connecting the input/output pad 2210 and the package upper pads 2130. Therefore, in each of the first and second semiconductor packages 2003a and 2003b, the semiconductor chips 2200 may be electrically connected to each other in a bonding wire manner, and may be electrically connected to the package upper pads 2130 of the package substrate 2100. According to embodiments, in each of the first and second semiconductor packages 2003a and 2003b, the semiconductor chips 2200 may be electrically connected to each other by a connection structure including a through-silicon-via (TSV), instead of the connection structure 2400 in a bonding wire manner.

According to one or more embodiments, the controller 2002 and the semiconductor chips 2200 may be included in one package. According to one or more embodiments, the controller 2002 and the semiconductor chips 2200 may be mounted on a separate interposer substrate, different from the main substrate 2001, and the controller 2002 and the semiconductor chips 2200 may be connected to each other by wiring formed on the interposer substrate.

In a structure in which two or more semiconductor structures are joined, before joining the semiconductor structures, a process of removing a conductive material remaining in a head portion of a separation region may be added, thereby preventing leakage current occurring when the conductive material remaining in the head portion of the separation regions is in contact with a first conductive layer, and preventing a defect occurring when the conductive material remaining is separated from the separation regions during the process. Therefore, a semiconductor device having improved reliability and a data storage system including the same may be provided.

In another example embodiment, a method for manufacturing a semiconductor device includes alternately stacking interlayer insulating layers and sacrificial insulating layers to be stacked in a first direction, perpendicular to an upper surface of a substrate, to form a mold structure; forming channel holes penetrating through the mold structure in the first direction, and separation holes spaced apart in a second direction, perpendicular to the first direction; expanding the separation holes to form a separation region opening being continuous in the second direction; removing the sacrificial insulating layer through the separation region openings; forming a first-side insulating layer on the separation region opening; depositing a conductive material between the interlayer insulating layers of the mold structure to form a gate electrode and to form a stack structure; forming a second-side insulating layer surrounding an inner side surface of the first-side insulating layer disposed on the separation region opening; removing the second-side insulating layer disposed on a lower surface of the separation region opening; removing the conductive material remaining on the lower surface of the separation region opening; removing the first-side insulating layer disposed on the lower surface of the separation region opening; and burying a buried insulating layer in the separation region opening to form a separation region structure.

The forming a separation region structure may include forming a separation region through portion penetrating through the stack structure and a separation region head portion protruding into the substrate.

In the forming a first-side insulating layer, bending and extending the first-side insulating layer to a region from which the sacrificial insulating layer is removed, to form a second horizontal insulating layer between the interlayer insulating layers, may be included.

The forming a first-side insulating layer may include depositing aluminum oxide (Al₂O₃) or hafnium oxide (HfO₂), which is a high-κ material.

The forming a first-side insulating layer may include removing the conductive material of the separation region opening; and forming the first-side insulating layer along a side surface and a lower surface of the separation region opening, and a space may be formed between the side surface of the separation region opening and side surfaces of the gate electrodes.

In the separation region opening, a width of a shape penetrating through the mold structure may be greater than a width of a shape penetrating through the substrate.

The conductive material remaining in a region corresponding to the head portion of the separation region in the separation region opening may include molybdenum (Mo) or tungsten (W).

The channel hole and the separation hole may be formed by the same hole forming process.

In the forming a second-side insulating layer, forming the second-side insulating layer extending into a space between the gate electrodes and a side surface of the separation region opening, to form a first horizontal insulating layer, may be included.

In the forming a separation region structure, the second-side insulating layer and the buried insulating layer may include different materials.

While one or more embodiments have been illustrated and described above, it will be apparent to those skilled in the art that modifications and variations could be made without departing from the scope of the present disclosure as defined by the appended claims.

What is claimed is:

1. A semiconductor device comprising:
a stack structure comprising interlayer insulating layers and gate electrodes stacked in a first direction;
a channel structure penetrating through the stack structure to extend in the first direction;
a conductive layer on the stack structure; and
separation regions penetrating through the stack structure to extend in a second direction perpendicular to the first direction, and spaced apart from each other in a third direction perpendicular to the first direction and the second direction,
wherein each of the separation regions comprises:
a separation region through portion penetrating through the stack structure;
at least one separation region head portion protruding into the conductive layer; and
side protrusion portions protruding from a side surface of the separation region through portion toward the gate electrodes, wherein the side protrusion portions are spaced apart from each other in the first direction;
a first-side insulating layer between the separation regions and the gate electrodes;
a second-side insulating layer on an inner side surface of the first-side insulating layer; and
a buried insulating layer on an inner side surface of the second-side insulating layer, and
wherein each of the side protrusion portions of each of the separation regions comprises:
a first horizontal insulating layer comprising a portion of the second-side insulating layer protruding toward one of the gate electrodes; and
a second horizontal insulating layer comprising a portion of the first-side insulating layer folded along the first horizontal insulating layer, wherein the second horizontal insulating layer of each of the side protrusion portions is in contact with an upper surface of the first horizontal insulating layer of a first side protrusion portion among the side protrusion portions and is in contact with a lower surface of the first horizontal insulating layer of a second side protrusion portion among the side protrusion portions, wherein the first side protrusion portion is adjacent to the second side protrusion portion in the first direction.

2. The semiconductor device of claim 1, wherein the second-side insulating layer comprises a different material from the buried insulating layer.

3. The semiconductor device of claim 1, wherein the stack structure comprises an uppermost interlayer insulating layer on a lower surface of the conductive layer, and
wherein the first-side insulating layer is folded at a same level as an upper surface of the uppermost interlayer insulating layer, and is on at least a portion of an upper surface of the separation region through portion.

4. The semiconductor device of claim 3, wherein an upper surface of the second-side insulating layer is in contact with the first-side insulating layer and the buried insulating layer.

5. The semiconductor device of claim 3, wherein an upper surface of the second-side insulating layer is entirely in contact with the first-side insulating layer.

6. The semiconductor device of claim 1, wherein an upper surface of the second-side insulating layer is entirely in contact with the buried insulating layer.

7. The semiconductor device of claim 1, wherein the second-side insulating layer is spaced apart from an upper surface of the separation region through portion.

8. The semiconductor device of claim 1, wherein the channel structure comprises:
a channel structure through portion penetrating through the stack structure and a channel structure head portion protruding into the conductive layer;
a channel layer extending from the channel structure through portion to the channel structure head portion; and
a channel dielectric layer between the stack structure and the channel layer, and
wherein the channel layer of the channel structure head portion and the buried insulating layer of the at least one separation region head portion of the separation regions are entirely in contact with the conductive layer.

9. The semiconductor device of claim 1, wherein an upper surface of the at least one separation region head portion has a first width, a lower surface of the at least one separation region head portion has a second width, and the first width is smaller than the second width.

10. The semiconductor device of claim 9, wherein an upper surface of the separation region through portion has a third width, and the third width is at least twice the second width.

11. The semiconductor device of claim 9, wherein the side protrusion portions of each of the separation regions have a fourth width in the first direction, and the second is at least twice the fourth width.

12. The semiconductor device of claim 1, wherein the channel structure comprises channel portions penetrating through the stack structure and connected in the first direction, and channel bending portions between the channel portions,
wherein the separation region through portion comprises separation region portions penetrating through the stack structure and connected in the first direction, and separation region bending portions between the separation region portions, and
wherein one of the channel bending portions and one of the separation region bending portions is located at a same level.

13. A semiconductor device comprising:
a first semiconductor structure comprising a first substrate, a circuit element on the first substrate, a lower interconnection structure connected to the circuit element, and a lower bonding structure connected to the lower interconnection structure; and
a second semiconductor structure on the first semiconductor structure, the second semiconductor structure comprising an upper bonding structure bonded to the lower bonding structure,
wherein the second semiconductor structure comprises:
a conductive layer;
a stack structure below the conductive layer and comprising interlayer insulating layers and gate electrodes, stacked in a first direction perpendicular to an upper surface of the conductive layer;
an upper interconnection structure below the stack structure and joined to the upper bonding structure;
a channel structure comprising a channel layer joined to the conductive layer, the channel structure penetrating through the stack structure in the first direction; and
a separation region,
wherein the separation region comprises:
a separation region through portion penetrating through the stack structure in a second direction perpendicular to the first direction;
separation region head portions protruding from the separation region through portion into the conductive layer and spaced apart from each other in the second direction,
a side insulating layer contacting a side surface of the separation region through portion;
a buried insulating layer in an inside of the side insulating layer; and
an upper buried insulating layer extending in the first direction from the buried insulating layer and protruding into an internal portion of the conductive layer from the separation region head portions, and
wherein the upper buried insulating layer is in contact with the conductive layer.

14. The semiconductor device of claim 13, wherein the side insulating layer comprises a different material from the buried insulating layer.

15. The semiconductor device of claim 13, further comprising an inner side insulating layer between the stack structure and the side insulating layer.

16. The semiconductor device of claim 15, further comprising side protrusion portions protruding from the side surface of the separation region through portion toward the gate electrodes and spaced apart from each other in the first direction,
wherein the inner side insulating layer extends along the side protrusion portions and is on upper and lower surfaces of each of the side protrusion portions.

17. The semiconductor device of claim 13, wherein a lower surface of each of the separation region head portions has a second width, an upper surface of the separation region through portion has a third width, the second width is smaller than the third width, and
wherein a bending portion is between the separation region head portions and the separation region through portion.

18. The semiconductor device of claim 13, wherein the channel structure comprises a channel structure through portion penetrating through the stack structure and a channel structure head portion protruding into the conductive layer, the channel structure head portion having a first height from a lower surface of the conductive layer in the first direction,
wherein the separation region head portions have a second height from the lower surface of the conductive layer in the first direction, and
wherein the first height and the second height are substantially the same.

19. The semiconductor device of claim 18, wherein the channel layer of the channel structure head portion and the upper buried insulating layer of the separation region are entirely in contact with the conductive layer.

20. A semiconductor device comprising:
a semiconductor device comprising an input/output pad; and
a controller connected to the semiconductor device through the input/output pad and configured to control the semiconductor device,
wherein the semiconductor device comprises:
a stack structure comprising interlayer insulating layers and gate electrodes stacked in a first direction;
a channel structure penetrating through the stack structure to extend in the first direction;
a conductive layer on the stack structure; and
separation regions penetrating through the stack structure to extend in a second direction perpendicular to the first direction, and spaced apart from each other in a third direction perpendicular to the first direction and the second direction,
wherein each of the separation regions comprises:
a separation region through portion penetrating through the stack structure;
at least one separation region head portion protruding into the conductive layer; and
side protrusion portions protruding from a side surface of the separation region through portion toward the gate electrodes, wherein the side protrusion portions are spaced apart from each other in the first direction;
a first-side insulating layer between the separation regions and the gate electrodes;
a second-side insulating layer on an inner side surface of the first-side insulating layer; and
a buried insulating layer on an inner side surface of the second-side insulating layer, and
wherein each of the side protrusion portions of each of the separation regions comprises:
a first horizontal insulating layer comprising a portion of the second-side insulating layer protruding toward one of the gate electrodes; and
a second horizontal insulating layer comprising a portion of the first-side side insulating layer folded along the first horizontal insulating layer, wherein the second horizontal insulating layer of each of the side protrusion portions is in contact with an upper surface of the first horizontal insulating layer of a first side protrusion portion among the side protrusion portions and is in contact with a lower surface of the first horizontal insulating layer of a second side protrusion portion among the side protrusion portions, wherein the first side protrusion portion is adjacent to the second side protrusion portion in the first direction.
